(19) United States
(12) Patent Application Publication
(10) Pub. No.: US 2020/0187371 A1
(43) Pub. Date: Jun. 11, 2020

(54) NON-CONTACT HIGH VOLTAGE SENSOR

(71) Applicant: Standard Electric Works Co.,Ltd., New Taipei City (TW)

(72) Inventors: Shui-Yuan HSIEH, New Taipei City (TW); Yu-Chao Chen, New Taipei City (TW)

(21) Appl. No.: 16/271,898

(22) Filed: Feb. 11, 2019

(30) Foreign Application Priority Data
Dec. 6, 2018 (TW) 107216625

(51) Int. Cl. H05K 5/00; H05K 7/14; H05K 1/18; H05K 9/00; H05K 5/02; G01R 15/14; G01R 19/00

(52) U.S. Cl. CPC H05K 5/0086; H05K 7/1434; H05K 1/181; H05K 9/0022; H05K 5/0217; H05K 2201/10113; G01R 19/0084; H05K 2201/09027; H05K 2201/10151; H05K 2201/10083; H05K 2201/10121; G01R 15/14

(57) ABSTRACT

A non-contact high voltage sensor includes a sensing head and a battery holder. The sensing head includes a control circuit board, a metal sensing plate and an insulating housing, and the insulating housing encloses the control circuit board and the metal sensing plate. The control circuit board is electrically connected to the metal sensing plate to sense high voltages in a surrounding environment, and the metal sensing plate includes a central flat portion and an arc-shaped portion, and the arc-shaped portion is extending from a boundary of the central flat portion and bent towards the control circuit board.

### CROSS-REFERENCE TO RELATED APPLICATION

This application claims priority to Taiwan Application Serial Number 107216625, filed Dec. 6, 2018 which is herein incorporated by reference in its entirety.

### BACKGROUND

### Field of Invention

The present disclosure relates to a voltage sensor, more particular to a non-contact type voltage sensor.

### Description of Related Art

A non-contact high-voltage sensor is one of the important tools to prevent a person from electric shock. A general user can couple a rod to support the non-contact high-voltage sensor such that the person can sense a position of a potentially high voltage source that is farther from the user.

A sensing head design of the conventional non-contact high voltage sensor has a limited angle or range of perception. If you want to increase the angle or range of perception, the design of the sensing head needs to increase its volume, but a larger volume of the sensing head is inconvenient to carry and use.

### SUMMARY

The present invention provides a non-contact high voltage sensor to deal with the needs of the prior art problems.

In one or more embodiments, a non-contact high voltage sensor includes a sensing head and a battery holder that are electrically coupled to each other. The sensing head includes a control circuit board, a metal sensing plate and an insulating housing, and the insulating housing encloses the control circuit board and the metal sensing plate. The control circuit board is electrically connected to the metal sensing plate to sense high voltages in a surrounding environment, and the metal sensing plate includes a central flat portion and an arc-shaped portion, and the arc-shaped portion is extending from a boundary of the central flat portion and bent towards the control circuit board.

In one or more embodiments, the central flat portion is a circular flat plate and in substantially parallel with the control circuit board.

In one or more embodiments, the arc-shaped portion is part of a spherical surface.

In one or more embodiments, the non-contact high voltage sensor further includes an electromagnetic shielding shell, which is at least partially between the metal sensing plate and the control circuit board, and the electromagnetic shielding shell is electrically connected to a negative electrode of the battery holder.

In one or more embodiments, the non-contact high voltage sensor further includes a securing portion coupled to a support rod, and the battery holder interconnects between the sensing head and the securing portion.

In one or more embodiments, the sensing head further includes a lighting device that is exposed through a cutout of the arc-shaped portion.

In one or more embodiments, the sensing head further includes a buzzer mounted on the control circuit board.

In one or more embodiments, the sensing head further includes a perceptual voltage regulator mounted on the control circuit board.

In one or more embodiments, the buzzer and the perceptual voltage regulator are located on a same side of the control circuit board.

In one or more embodiments, the battery holder includes a battery receiving cavity to load batteries.

In summary, the non-contact high voltage sensor disclosed herein has a metal sensing plate with an arc-shaped portion or as part of a sphere such that a sensing angle or range of the sensing head is improved, and the sensing sensitivity can be simultaneously improved. The electromagnetic shielding shell is electrically connected to a negative electrode of the battery holder to achieve the grounding effect that it can shield the control circuit board from electromagnetic interference of the metal sensing plate or external high voltage sources, and avoid high voltage associated damages.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a perspective view of a non-contact high voltage sensor according to one embodiment of the present disclosure;

FIG. 2 illustrates a cross-sectional view of the non-contact high voltage sensor in FIG. 1;

FIG. 3 illustrates a perspective view of the non-contact high voltage sensor in FIG. 1 with its insulating housing and electromagnetic shielding shell removed; and

FIG. 4 illustrates a bottom view of the non-contact high voltage sensor in FIG. 1.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

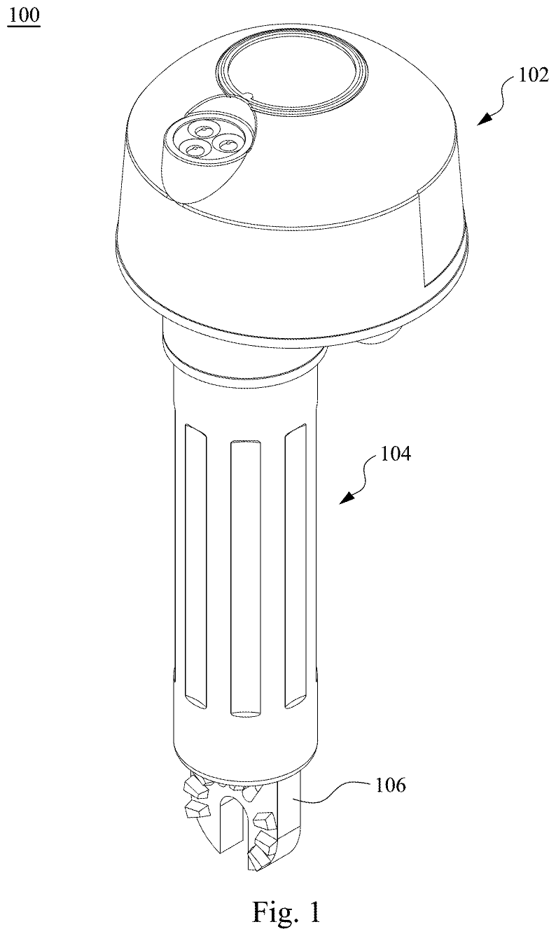

Reference is made to FIG. 1, which illustrates a perspective view of a non-contact high voltage sensor 100 according to one embodiment of the present disclosure. The non-contact high voltage sensor 100 includes a sensing head 102, a battery holder 104 and a securing portion 106. The sensing head 102 is electrically connected to the battery holder 104 such that the battery holder 104 with batteries loaded can supply necessary electric power to the operating sensing head 102. The securing portion 106 may be coupled to a support rod (not shown in drawings) according to actual demands, and the battery holder 104 interconnects between the sensing head 102 and the securing portion 106. In other embodiments, the securing portion 106 may not be a necessary design.

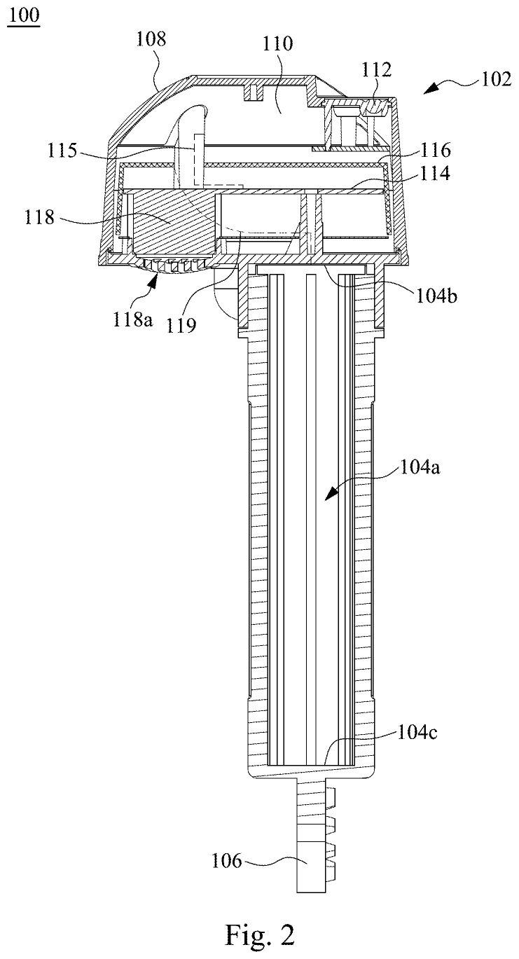

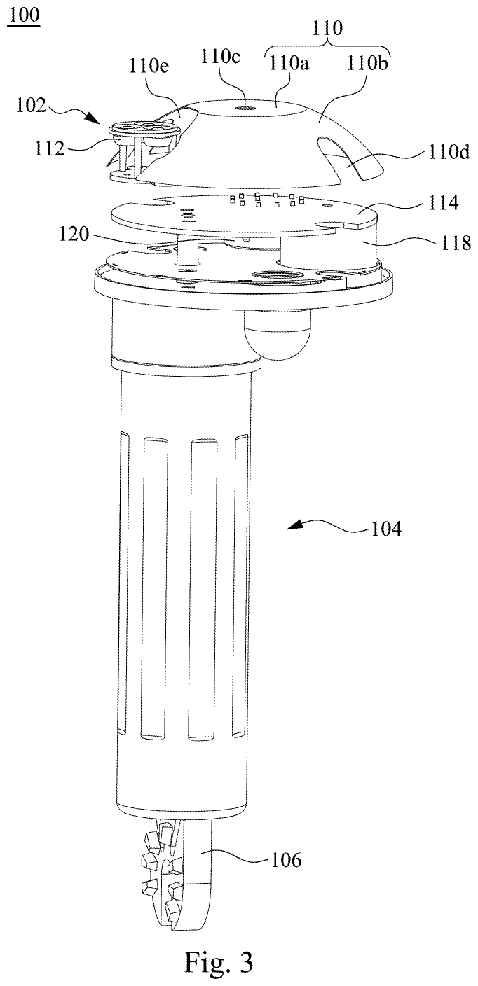

Reference is made to FIGS. 2 and 3. FIG. 2 illustrates a cross-sectional view of the non-contact high voltage sensor in FIG. 1, and FIG. 3 illustrates a perspective view of the non-contact high voltage sensor in FIG. 1 with its insulating housing and electromagnetic shielding shell removed. A sensing head 102 of the non-contact high voltage sensor includes a control circuit board 114, a metal sensing plate 110 and an insulating housing 108. The insulating housing 108 has a hollow space inside to enclose the control circuit board 114 and the metal sensing plate 110 such that the metal sensing plate 110 and/or the control circuit board 114 can be insolate from an external environment, e.g., a person or a potentially high voltage source. The control circuit board 114 is electrically connected to the metal sensing plate 110 so as to sense to high voltages in a surrounding environment. The metal sensing plate 110 and the control circuit board 114 are spaced from each other within the insulating housing 108, but are electrically connected to each other by conductive paths, e.g., a conductive path 115.

In this embodiment, the metal sensing plate 110 includes a central flat portion 110a and an arc-shaped portion 110b, and the arc-shaped portion 110b is extended from an outer, circumferential boundary of the central flat portion 110a and bent towards the control circuit board 114.

In this embodiment, the central flat portion 110a of the metal sensing plate 110 has an area smaller than an area of the control circuit board 114. In addition, the central flat portion 110a is a circular flat plate and in substantially parallel with the control circuit board 114, but not being limited thereto.

In this embodiment, the arc-shaped portion 110b of the metal sensing plate 110 is part of a spherical surface or part of a sphere. In other embodiments, the whole metal sensing plate may be part of a spherical surface or part of a sphere, i.e., the central flat portion is modified as part of a spherical surface or part of a sphere. Compared with a conventional purely-flat sensing plate, the sensing head 102 is designed to have an improved angle or range of perception by modifying the shape of its metal sensing plate 110, and the sensitivity of the metal sensing plate 110 can be simultaneously improved.

In this embodiment, the sensing head 102 further includes an electromagnetic shielding shell 116 that is wrapped around the control circuit board 114, and has at least a part, e.g., a top ceiling portion of the shielding shell 116, located between the metal sensing plate 110 and the control circuit board 114. The electromagnetic shielding shell 116 is electrically connected to a negative electrode 104b of the battery holder 104 to achieve a grounding purpose, i.e., being electrically connected to the negative electrode 104b of the battery holder 104 and a negative electrode of a battery contained inside via a conductive path 11, such that the electromagnetic shielding shell 116 may shield the control circuit board 114 from electromagnetic interference of the metal sensing plate 110 or external high voltage sources, and avoid high voltage associated damages.

In this embodiment, the sensing head 102 may further include a buzzer 118 mounted on a surface of the control circuit board 114. The buzzer 118 is used to sound an alarm when the sensing head 102 senses the presence of a high voltage.

In this embodiment, the sensing head 102 may further include a perceptual voltage regulator 120 mounted on a surface of the control circuit board 114. The perceptual voltage regulator 120 is used to adjust a threshold voltage of the sensing head 102 to sense a high voltage source, e.g., the buzzer sounds an alarm when the sensed voltage is greater than the threshold.

In this embodiment, the buzzer 118 and the perceptual voltage regulator 120 are located on a same side of the control circuit board 114, i.e., a lower side or surface of the control circuit board 114 away from the metal sensing plate 110 and is surrounded by the electromagnetic shielding shell 116. That is, the control circuit board 114 and components mounted thereon are surrounded by the electromagnetic shielding shell 116 and thus isolated from electromagnetic interference of the metal sensing plate 110 or external high voltage sources, and avoid high voltage associated damages.

In this embodiment, the sensing head 102 may further includes a lighting device 112 that is exposed through a cutout 110e of the arc-shaped portion 110b. The lighting device 112, e.g., a light emitting diode, is used to provide a desired illumination when detecting a high voltage.

In this embodiment, the battery holder 104 may further includes a battery receiving cavity 104a for loading batteries inside thereof. The battery holder 104 has a positive electrode 104c and a negative electrode 104b used to contact the positive and negative electrodes of the batteries such that the batteries can supply necessary electric power to the operating sensing head 102. In addition, the electromagnetic shielding shell 116 is electrically connected to the negative electrode 104b of the battery holder 104, i.e., via the conductive path 119, and thus electrically connected to the negative electrodes of the batteries loaded inside the battery holder 104, to achieve a grounding purpose.

In this embodiment, the central flat portion 110a of the metal sensing plate 110 has a screw hole 110c through which a screw may be used to fasten the insulating housing 108, but not being limited thereto. The arc-shaped portion 110b of the metal sensing plate 110 may further have cutouts (110d, 110e), wherein the cutouts 110d are used to provide assembly space, and the cutouts 110e are used for the lighting device 112 to be exposed.

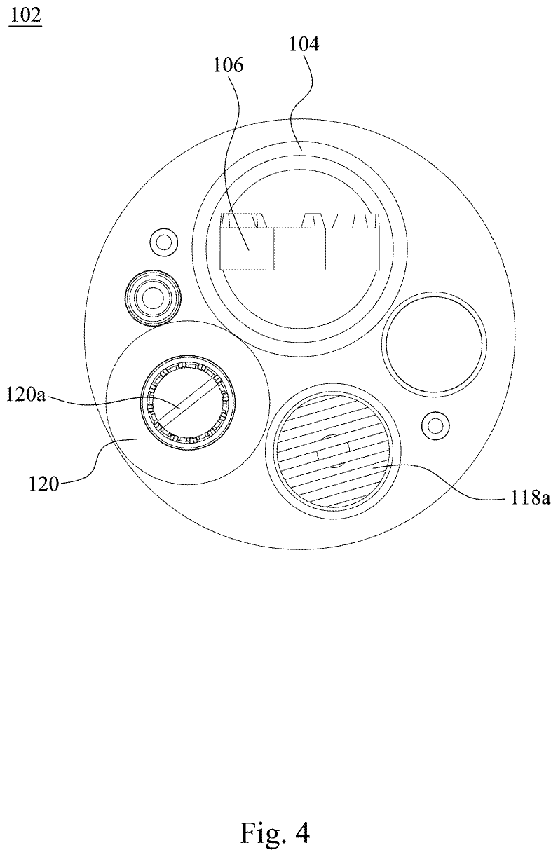

Reference is made FIG. 4, which illustrates a bottom view of the non-contact high voltage sensor in FIG. 1. As discussed above, the metal sensing plate 110 and the lighting device 112 is designed at an upper side of the sensing head 102 while the buzzer 118 and the perceptual voltage regulator 120 is designed at an lower side of the sensing head 102. The buzzer 118 has its sounding port 118a confronting the user when in use such that an alarm sound can be heard by the user quickly. The perceptual voltage regulator 120 has a knob 120a for the user to adjust a threshold voltage of the sensing head 102 to sense the high voltage, e.g., exceeding the preset threshold voltage, the buzzer will sound an alarm.

In summary, the non-contact high voltage sensor disclosed herein has a metal sensing plate with an arc-shaped portion or as part of a sphere such that a sensing angle or range of the sensing head is improved, and the sensing sensitivity can be simultaneously improved. The electromagnetic shielding shell is electrically connected to a negative electrode of the battery holder to achieve the grounding effect that it can shield the control circuit board from electromagnetic interference of the metal sensing plate or external high voltage sources, and avoid high voltage associated damages.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A non-contact high voltage sensor comprising a sensing head and a battery holder electrically coupled to each other, the sensing head including a control circuit board, a metal sensing plate and an insulating housing, the insulating housing enclosing the control circuit board and the metal sensing plate, the control circuit board is electrically connected to the metal sensing plate to sense high voltages in a surrounding environment, the metal sensing plate includes a central flat portion and an arc-shaped portion, and the arc-shaped portion extending from a boundary of the central flat portion and bent towards the control circuit board.

2. The non-contact high voltage sensor of claim 1, wherein the central flat portion is a circular flat plate and in substantially parallel with the control circuit board.

3. The non-contact high voltage sensor of claim 1, wherein the arc-shaped portion is part of a spherical surface.

4. The non-contact high voltage sensor of claim 1 further comprising an electromagnetic shielding shell, which is at least partially between the metal sensing plate and the control circuit board, the electromagnetic shielding shell is electrically connected to a negative electrode of the battery holder.

5. The non-contact high voltage sensor of claim 1 further comprising a securing portion coupled to a support rod, wherein the battery holder interconnects between the sensing head and the securing portion.

6. The non-contact high voltage sensor of claim 1, wherein the sensing head further comprises a lighting device that is exposed through a cutout of the arc-shaped portion.

7. The non-contact high voltage sensor of claim 1, wherein the sensing head further comprises a buzzer mounted on the control circuit board.

8. The non-contact high voltage sensor of claim 7, wherein the sensing head further comprises a perceptual voltage regulator mounted on the control circuit board.

9. The non-contact high voltage sensor of claim 8, wherein the buzzer and the perceptual voltage regulator are located on a same side of the control circuit board.

10. The non-contact high voltage sensor of claim 1, wherein the battery holder comprises a battery receiving cavity.
